(19) United States
(12) Patent Application Publication
(10) Pub. No.: US 2018/0151545 A1
(43) Pub. Date: May 31, 2018

(54) LIGHT-EMITTING DEVICE AND LIGHT-EMITTING MODULE USING THE SAME

(71) Applicant: Genesis Photonics Inc., Tainan City (TW)

(72) Inventors: Yi-Ru Huang, Tainan City (TW); Shao-Ying Ting, Tainan City (TW); Kuan-Chieh Huang, New Taipei City (TW); Jing-En Huang, Tainan City (TW)

(21) Appl. No.: 15/878,592

(22) Filed: Jan. 24, 2018

Related U.S. Application Data
(63) Continuation of application No. 15/131,143, filed on Apr. 18, 2016, now abandoned.
(60) Provisional application No. 62/148,761, filed on Apr. 17, 2015.

(51) Int. Cl. H01L 25/075

(52) U.S. Cl. CPC H01L 25/0753; H01L 2224/73265; H01L 2224/48464; H01L 33/44; H01L 2224/16145; H01L 2224/4813

(57) ABSTRACT

A light-emitting device and a light-emitting module using the same are provided. The light-emitting device includes a substrate module and a light-emitting component. The substrate module includes a substrate, a first conductive layer, an insulation layer and a second conductive layer. The substrate has an upper surface. The insulation layer is formed on the upper surface of the substrate, separates the substrate and the first conductive layer and has an opening. The second conductive layer connects to the upper surface of the substrate and is separated from the first conductive layer. The light-emitting component is disposed on the substrate module and electrically connected to the first conductive layer and the second conductive layer.

This application is a continuation application of co-pending application Ser. No. 15/131,143, filed on Apr. 18, 2016, which claims the benefit of U.S. application Ser. No. 62/148,761, filed Apr. 17, 2015, the subject matter of which is incorporated herein by reference.

### BACKGROUND OF THE INVENTION

### Field of the Invention

The invention relates in general to a light-emitting device and a light-emitting module using the same, and more particularly to a light-emitting device capable of receiving a wire and a light-emitting module using the same.

### Description of the Related Art

Conventional vertical light-emitting diode generally uses wires to connect a semiconductor layer and an external device such as a circuit board. However, it is difficult to form an Ohmic contact between wires and the semiconductor layer of a light-emitting diode, therefore the device operation may be adversely affected by wire bonding.

Therefore, how to provide a solution for forming an excellent Ohmic contact between wires and the semiconductor layer has become a prominent task for the industries.

### SUMMARY OF THE INVENTION

The invention is directed to a light-emitting device and a light-emitting module using the same capable of resolving the problems encountered in the prior art.

According to one embodiment of the present invention, a light-emitting device is provided. The light-emitting device includes a substrate module and a first light-emitting component. The substrate module includes a substrate, a first conductive layer, a first insulation layer and a second conductive layer. The substrate has an upper surface. The first insulation layer having an opening is formed on the upper surface of the substrate and separates the substrate and the first conductive layer. The second conductive layer and the first conductive layer are separated and connected to the upper surface of the substrate through the opening. The first light-emitting component is disposed on the substrate module and electrically connected to the first conductive layer and the second conductive layer.

According to another embodiment of the present invention, a light-emitting device is provided. The light-emitting device includes a substrate module and a first light-emitting component. The substrate module includes a substrate, a first conductive layer, a first insulation layer and a second conductive layer. The substrate has an upper surface. The substrate has an upper surface. The first insulation layer is formed on the upper surface of the substrate and separates the substrate and the first conductive layer. The second conductive layer and the first conductive layer are separated. The first light-emitting component having a first element lateral side is disposed on the substrate module and electrically connected to the first conductive layer and the second conductive layer. A first wire receiving portion is formed among the first conductive layer, the first substrate lateral side and the first element lateral side.

According to an alternate embodiment of the present invention, a light-emitting module is provided. The light-emitting module includes a circuit board, a first wire and the light-emitting device described above. The light-emitting device is disposed on the circuit board. The first wire connects the first conductive layer of the light-emitting device and the circuit board.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a cross-sectional view of a light-emitting device according to an embodiment of the invention.

FIG. 2 shows a cross-sectional view of a light-emitting device according to another embodiment of the invention.

FIG. 3A shows a cross-sectional view of a light-emitting device according to another embodiment of the invention.

FIG. 3B shows a top view of the light-emitting device of FIG. 3A.

FIG. 4 shows a cross-sectional view of a light-emitting module according to an embodiment of the invention.

FIG. 5A shows a cross-sectional view of a light-emitting device according to another embodiment of the invention.

FIG. 5B shows a cross-sectional view of a light-emitting module according to another embodiment of the invention.

FIG. 6 shows a cross-sectional view of a light-emitting device according to another embodiment of the invention.

FIG. 7 shows a cross-sectional view of a light-emitting module according to an embodiment of the invention.

FIG. 8 shows a cross-sectional view of a light-emitting module according to another embodiment of the invention.

FIG. 9 shows a cross-sectional view of a light-emitting device according to another embodiment of the invention.

FIG. 10 shows a cross-sectional view of a light-emitting module according to another embodiment of the invention.

### DETAILED DESCRIPTION OF THE INVENTION

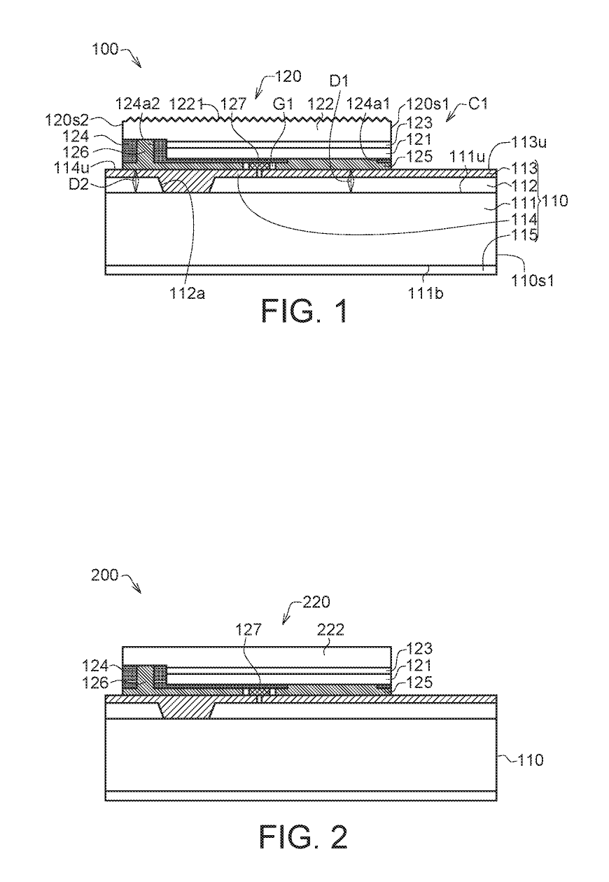

FIG. 1 shows a cross-sectional view of a light-emitting device 100 according to an embodiment of the invention. The light-emitting device 100 includes a substrate module 110 and a first light-emitting component 120.

The substrate module 110 includes a substrate 111, an insulation layer 112, a first conductive layer 113, a second conductive layer 114 and a third conductive layer 115.

In the present embodiment, the substrate 111, such as a conductive is substrate, can be selected from aluminum, silver, gold, platinum or combinations thereof. Or, the materials of the substrate 111, such as a semiconductor substrate, can be selected from silicon (Si), p-Si, n-Si, germanium,silicon carbide, zinc oxide or combinations thereof.

The substrate 111 has an upper surface 111u and a lower surface 111b. The insulation layer 112 can be formed on the upper surface 111u of the substrate 111 to separate the substrate 111 from the first conductive layer 113 to avoid short-circuit between the first conductive layer 113 and the second conductive layer 114 through the substrate 111. In an embodiment, the insulation layer 112 can be formed of silicon oxide, nitride or other suitable materials.

The first conductive layer 113 and the second conductive layer 114 are formed on the insulation layer 112. The insulation layer 112 has a first opening 112a through which the second conductive layer 114 connects the upper surface 111u of the substrate 111 and therefore the second conductive layer 114 is electrically connected to the substrate 111. The distance D1 from a top surface 11 3u of the first conductive layer 113 to the substrate 111 is equal to the distance D2 from a top surface 114u of the second conductive layer 114 to the substrate 111. The top surface 113u of the first conductive layer 113 is substantially coplanar with the top surface 114u of the second conductive layer 114. As indicated in FIG. 1, the second conductive layer 114 of the present embodiment delivers the current through the first opening 112a along a thickness direction of the substrate. Moreover, the third conductive layer 115 can be formed on the lower surface 111b of the substrate 111, and the substrate 111 can be electrically connected to an external device, such as a circuit board (not illustrated), through the third conductive layer 115.

The first light-emitting component 120 is disposed on the substrate module 110 and electrically connected to the first conductive layer 113 and the second conductive layer 114. For example, the first light-emitting component 120 includes a first type semiconductor layer 121, a second type semiconductor layer 122, a light-emitting layer 123, a second insulation layer 124, a first electrode 125, a second electrode 126 and an insulating pad 127.

The first type semiconductor layer 121 can be an N type semiconductor layer, and the second type semiconductor layer 122 can be a P type semiconductor layer. Or, the first type semiconductor layer 121 can be a P type semiconductor layer, arid the second type semiconductor layer 122 can be an N type semiconductor layer. In terms of material, the P type semiconductor layer can be a GaN-based semiconductor layer doped with magnesium (Mg) and the N type semiconductor layer can be a GaN-based semiconductor layer doped with silicon (Si), but the invention is not limited thereto.

In the present embodiment, the second type semiconductor layer 122 has a patterned structure 1221, including but not limited to a conical structure, a triangular pyramid structure, a hexagonal crystalline structure or an irregular rough structure. The patterned structure 1221 can increase light extraction efficiency of the light-emitting device 100.

The light-emitting layer 123 is interposed between the first type semiconductor layer 121 and the second type semiconductor layer 122. The light-emitting layer 123 can be an InxAlyGa1-x-yN (0≤x, 0≤y, x+y≤1) structure or can be doped with silicon (Si). In an embodiment, the light-emitting layer 123 can be a single-layer or multi-layer structure.

The second insulation layer 124 having a second opening 124a1 and a third opening 124a2 is formed on the first type semiconductor layer 121 and the second type semiconductor layer 122.

The first electrode 125 is connected to the first type semiconductor layer 121 through the second opening 124a1 for electrically connection. The second electrode 126 can be connected to the second type semiconductor layer 122 through the third opening 124a2 for electrically connection. The first electrode 125 and the second electrode 126 are respectively connected to the first conductive layer 113 and the second conductive layer 114, such that the current can be delivered to the first electrode 125 and the second electrode 126 through the first conductive layer 113 and the second conductive layer 114 to cause the light-emitting layer 123 emitting light. The second electrode 126 can be extended to and disposed on the second type semiconductor layer 122, and is separated from the second type semiconductor layer 122 by the second insulation layer 124.

The first electrode 125 can be a single-layer or multi-layer structure formed of at least one of gold, aluminum, silver, copper, rhodium (Rh), ruthenium (Ru), palladium (Pd), iridium (Ir), platinum (Pt), chromium, tin, nickel, titanium, tungsten (W), chromium alloy, titanium-tungsten alloy, nickel alloy, copper-silicon alloy, aluminum-copper-silicon alloy, aluminum silicon alloy, gold-tin alloy and combinations thereof, but the invention is not limited thereto. The material of the second electrode 126 is similar to that of the first electrode 125, and does not repeat here. The second insulation layer 124 can be such as a single oxide insulation layer (including a silicon oxide or a silicon nitride layer) or an insulating structure formed of multiple stacked oxide layers with different refractivities (including but not limited to Bragg reflector), or combinations thereof.

The insulating pad 127 can be formed on the second insulation layer 124 and located at a first gap G1 between the first electrode 125 and the second electrode 126. The insulating pad 127 can abut on at least one of the first conductive layer 113 and the second conductive layer 114 to avoid or reduce the possibility of generating cracks between the first electrode 125 and the second electrode 126 of the first light-emitting component 120. The top surface 113u of the first conductive layer 113 is substantially coplanar with the top surface 114u of the second conductive layer 114. Therefore, when the insulating pad 127 concurrently contacts the top surface 113u of the first conductive layer 113 and the top surface 114u of the second conductive layer 114, the insulating pad 127 can uniformly contact the first conductive layer 113 and the second conductive layer 114.

As indicated in FIG. 1, the substrate module 110 has a first substrate lateral side 110s1. The first light-emitting component 120 has a first element lateral side 120s1. A first wire receiving portion C1 is formed among the first conductive layer 113, the first substrate lateral side 110s1 and the first element lateral side 120s1 to receive a wire (described below). Due to the design of the first wire receiving portion C1, the first conductive layer 113 is exposed by the first wire receiving portion C1, such that the tool head for wire bonding can enter the first wire receiving portion C1 to conveniently form a wire on the exposed first conductive layer 113. Thus, the current can be delivered between the first light-emitting component 120 and an external device through the first conductive layer 113 and the wire.

Besides, since the light-emitting device 100 can be electrically connected to an external device through the wire, the substrate 111 of the light-emitting device 100 can omit the via used for electrically connecting to an external device.

FIG. 2 shows a cross-sectional view of a light-emitting device 200 according to another embodiment of the invention. The light-emitting device 200 includes a substrate module 110 and a first light-emitting component 220. The first light-emitting component 220 includes a first type semiconductor layer 121, a second type semiconductor layer 222, a light-emitting layer 123, a second insulation layer 124, a first electrode 125, a second electrode 126 and an insulating pad 127. The light-emitting device 200 is different from the light-emitting device 100 in that the second type semiconductor layer 222 of the first light-emitting component 220 of the present embodiment does not have a patterned structure 1221.

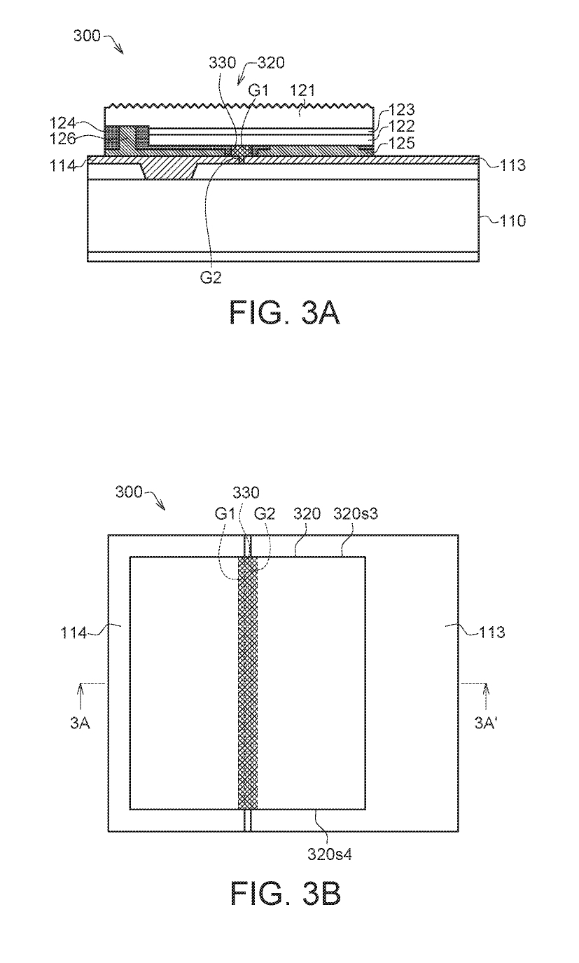

FIG. 3A shows a cross-sectional view of a light-emitting device 300 according to another embodiment of the invention. FIG. 3B shows a top view of the light-emitting device 300 of FIG. 3A. FIG. 3A is a cross-sectional view of the light-emitting device 300 of FIG. 3B along a direction 3A-3A.

The light-emitting device 300 includes a substrate module 110, a first light-emitting component 320 and an insulating filling layer 330.

The first light-emitting component 320 includes a first type semiconductor layer 121, a second type semiconductor layer 122, a light-emitting layer 123, a second insulation layer 124, a first electrode 125 and a second electrode 126. The first light-emitting component 320 is different from the first light-emitting component 120 in that the first light-emitting component 320 of the present embodiment replaces the insulating pad 127 with the insulating filling layer 330 which can be formed of silicone, epoxy resin or other organic materials.

A first gap G1 is formed between the first electrode 125 and the second electrode 126. A second gap G2 is formed between the first conductive layer 113 and the second conductive layer 114. The insulating filling layer 330 fills up the first gap G1 and the second gap G2, wherein the first gap G1 has a width larger than or equal to that of the second gap G2, and a portion formed on the substrate 111 can be included in the second gap G2. The insulating filling layer 330 can fill up the first gap G1 and the second gap G2 to avoid or reduce the possibility of generating cracks between the first electrode 125 and the second electrode 126 of the first light-emitting component 320.

As indicated in FIG. 3B, the first light-emitting component 320 further includes a third element lateral side 320s3 and a fourth element lateral side 320s4 disposed oppositely. The first gap G1 and the second gap G2 extend to the fourth element lateral side 320s4 from the third element lateral side 320s3. Thus, during the process of forming the insulating filling layer 330, the insulating filling layer 330 can fill up the first gap G1 and the second gap G2 due to capillarity.

In another embodiment, the first light-emitting component 320 may further include an insulating pad 127. Under such design, the insulating pad 127 can be disposed in the first gap G1, and the insulating filling layer 330 can be filled up the second gap G2. Or, the insulating pad 127 is disposed in partial space of the first gap G1, and the insulating filling layer 330 fills up the remaining space of the first gap G1 and the entire second gap G2.

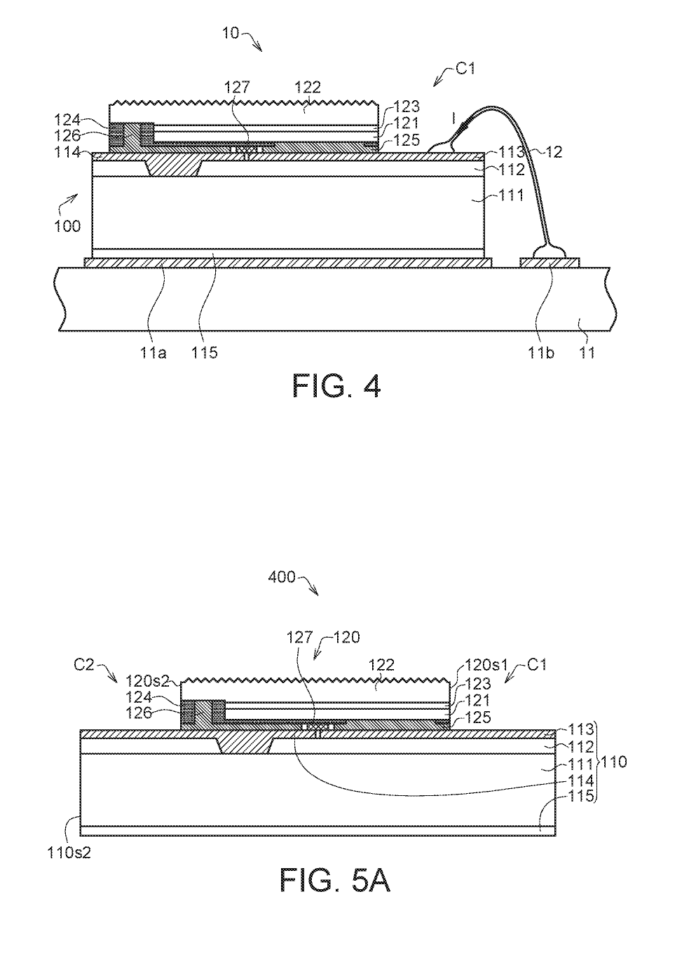

FIG. 4 shows a cross-sectional view of a light-emitting module 10 according to an embodiment of the invention. The light-emitting module 10 can be such as a bulb, a tube, a lamp or other products using the light-emitting device. The light-emitting module 10 includes a light-emitting device 100, a circuit board 11 and a wire 12. In another embodiment, the light-emitting device 100 can be replaced with the light-emitting device 200 or 300.

The light-emitting device 100 can be disposed on the circuit board 11. The circuit board 11 includes a first electrical pad 11a and a second electrical pad 11b. The substrate 111 of the light-emitting device 100 is electrically connected to the first electrical pad 11a through the third conductive layer 115, and the first conductive layer 113 of the light-emitting device 100 is electrically connected to the second electrical pad 11b through the first wire 12.

Since the first conductive layer 113 is exposed by the first wire receiving portion C1, the tool head for wire bonding can enter the first wire receiving portion C1 to bond the first wire 12 on the first conductive layer 113. As indicated in FIG. 4, the current I of the circuit board 11 is delivered downwards to the first conductive layer 113 through the first wire 12. Since the first conductive layer 113 is exposed by the light-emitting device 100, the first wire 12 can conveniently connect the first conductive layer 113 to form an Ohmic contact on the connection interface between the first wire 12 and the first conductive layer 113. In other embodiments, the insulating pad 127 of FIG. 4 can be replaced with the insulating filling layer 330 of FIG. 3A. In another embodiment, the light-emitting module 10 further includes a fluorescent adhesive layer (not illustrated) capable of covering the light-emitting device 100 and the first wire 12 to form a white light element.

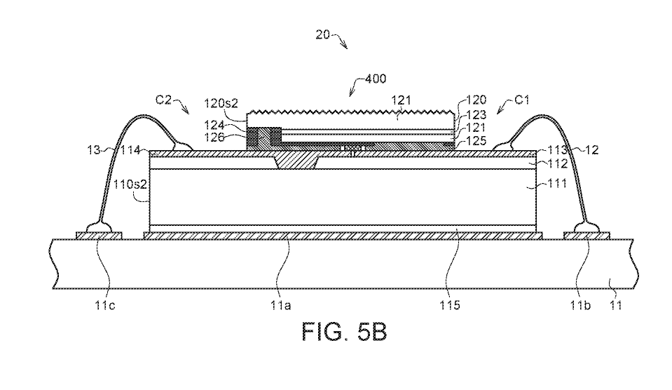

FIG. 5A shows a cross-sectional view of a light-emitting device 400 according to another embodiment of the invention. The light-emitting device 400 includes a substrate module 110 and a first light-emitting component 120.

The substrate module 110 and the first light-emitting component 120 respectively have a second substrate lateral side 110s2 and a second element lateral side 120s2. In comparison to the light-emitting devices 100, 200 and 300 disclosed above, the light-emitting device 400 of the present embodiment has a second wire receiving portion C2 formed among the second conductive layer 114, the second substrate lateral side 110s2 and the second element lateral side 120s2 to receive a wire (described below). Due to the design of the second wire receiving portion C2, the second conductive layer 114 is exposed by the second wire receiving portion C2 so that the tool head for wire bonding can enter the second wire receiving portion C2 to conveniently form a wire on the exposed second conductive layer 114.

Since the light-emitting device 400 of the present embodiment includes a first wire receiving portion C1 and a second wire receiving portion C2, a wire can be connected to the first conductive layer 113 exposed by the first wire receiving portion C1 and another wire can be connected to the second conductive layer 114 exposed by the second wire receiving portion C2, and the first light-emitting component 120 can be electrically connected to an external device through two wires. Thus, the substrate 111 of the substrate module 110 of the present embodiment can be an insulating substrate.

In other embodiments, the insulating pad 127 of FIG. 5A can be replaced with the insulating filling layer 330 of FIG. 3A.

FIG. 5B shows a cross-sectional view of a light-emitting module 20 according to another embodiment of the invention. The light-emitting module 20 includes a light-emitting device 400, a circuit board 11, a first wire 12 and a second wire 13. A second wire receiving portion C2 is formed among the second conductive layer 114, the second substrate lateral side 110s2 and the second element lateral side 120s2 to receive a wire. Due to the design of the second wire receiving portion C2, the second conductive layer 114 is exposed by the second wire receiving portion C2 such that the tool head for wire bonding can enter the second wire receiving portion C2 to conveniently form a wire on the exposed second conductive layer 114. Thus, the current can be delivered between the first light-emitting component 120 and external device through the second conductive layer 114 and the second wire 13. In other embodiments, the insulating pad 127 of FIG. 5A can be replaced with the insulating filling layer 330 of FIG. 3A.

As indicated in FIG. 5B, the light-emitting device 400 can be disposed on the circuit board 11. The circuit board 11 includes a first pad 11a, a second pad 11b and a third pad 11c. The first conductive layer 113 of the light-emitting device 100 is electrically connected to the second pad 11b through the first wire 12, and the second conductive layer 114 of the light-emitting device 100 is electrically connected to the third pad 11c through the second wire 13. Under such design, although the substrate 111 is an insulating substrate, the light-emitting device 400 still can be electrically connected to the circuit board 11 through the first wire 12 and the second wire 13. Besides, the third conductive layer 115 and the first pad 11a can be conductively or non-conductively connected. The light-emitting device 400 can further be connected to the first pad 11a through the third conductive layer 115, such that the heat generated by the light-emitting device 400 can be conducted to the circuit board 11 through the second electrode 126, the second conductive layer 114 disposed in the first opening 112a, the substrate 111, the third conductive layer 115 and the first pad 11a to dissipate the heat. In another embodiment, the heat generated by the light-emitting device 400 can be conducted to the circuit board 11 through the first electrode 125, the first conductive layer 113 disposed in the first opening 112a (not illustrated), the substrate 111, the third conductive layer 115 and the first pad 11a to dissipate the heat.

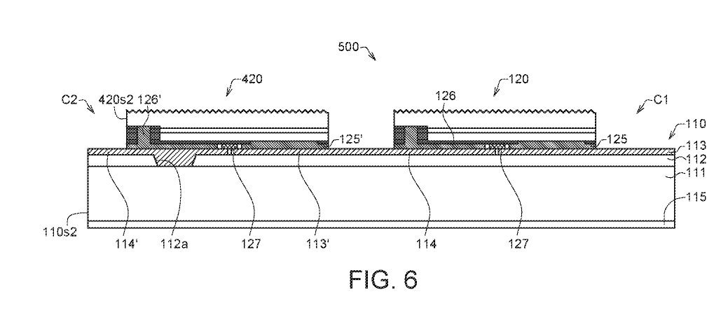

FIG. 6 shows a cross-sectional view of a light-emitting device 500 according to another embodiment of the invention. The light-emitting device 500 includes a substrate module 110, a first light-emitting component 120 and a second light-emitting component 420. The first light-emitting component 120 and the second light-emitting component 420 are disposed on the substrate module 110. The structure of the second light-emitting component 420 can be identical or similar to that of the first light-emitting component 120, and the similarities are not repeated here.

The substrate module 110 includes a substrate 111, an insulation layer 112, a first conductive layer 113, another first conductive layer 113′, a second conductive layer 114 and another second conductive layer 114′.

In the present embodiment, the first electrode 125 of the first light-emitting component 120 is connected to the first conductive layer 113; the second electrode 126 of the first light-emitting component 120 is connected to the second conductive layer 114; the first electrode 125′ of the second light-emitting component 420 is connected to the first conductive layer 113′; the second electrode 126′ of the second light-emitting component 420 is connected to the second conductive layer 114′. In the present embodiment, the second conductive layer 114 is disposed on the insulation layer 112 and is electrically connected to the first conductive layer 113′ disposed on the insulation layer 112, such that the second electrode 126 of the first light-emitting component 120 and the first electrode 125′ of the second light-emitting component 420 can be connected. The second conductive layer 114 and the first conductive layer 113′ can be the same conductive layer disposed on the substrate 111. For example, the second conductive layer 114 and the first conductive layer 113′ can be formed in the same manufacturing process together, to form the conductive layer in the same layer.

The insulation layer 112 has a first opening 112a. The second conductive layer 114′ can be electrically connected to the substrate 111 and the third conductive layer 115 through the first opening 112a, such that the substrate 111 can be electrically to an external device through the third conductive layer 115. The second conductive layer 114′ delivers the current through the first opening 112a along a thickness direction of the substrate.

In another embodiment, the quantity of the first light-emitting component 120 and/or the second light-emitting component 420 of the light-emitting device 500 can be more than 1. In other embodiments, the insulating pad 127 of FIG. 6 can be replaced with the insulating filling layer 330 of FIG. 3A.

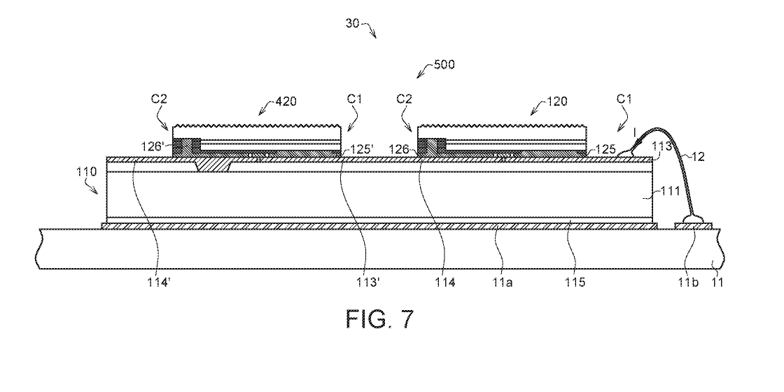

FIG. 7 shows a cross-sectional view of a light-emitting module 30 according to an embodiment of the invention. The light-emitting module 30 can be such as a bulb, a tube, a lamp or other products using the light-emitting device. The light-emitting module 30 includes a light-emitting device 500, a circuit board 11 and a first wire 12.

The light-emitting device 500 can be disposed on the circuit board 11. The circuit board 11 includes a first electrical pad 11a and a second electrical pad 11b. The substrate 111 of the light-emitting device 500 is electrically connected to the first electrical pad 11a through the third conductive layer 115. The first conductive layer 113 of the light-emitting device 500 is electrically connected to the second electrical pad 11 b through the first wire 12.

Since the first conductive layer 113 is exposed by the first wire receiving portion C1, the tool head for wire bonding can enter the first wire receiving portion C1 to bond the first wire 12 on the first conductive layer 113. As indicated in FIG. 7, the current I of the circuit board 11 is delivered downwards to the first conductive layer 113 through the first wire 12. Since the first conductive layer 113 is exposed by the light-emitting device 500, the first wire 12 can conveniently connect the first conductive layer 113 to form an excellent Ohmic contact on the connection interface between the first wire 12 and the first conductive layer 113. In other embodiments, the insulating pad 127 of FIG. 7 can be replaced with the insulating filling layer 330 of FIG. 3A. In another embodiment, the light-emitting module 30 further includes a fluorescent adhesive layer (not illustrated) capable of covering the light-emitting device 500 and the first wire 12 to form a white light element.

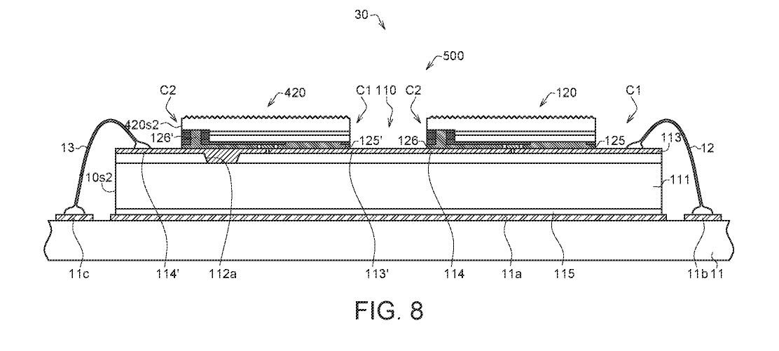

FIG. 8 shows a cross-sectional view of a light-emitting module 30 according to another embodiment of the invention. The light-emitting module 30 includes a light-emitting device 500, a circuit board 11, a first wire 12 and a second wire 13.

In the present embodiment, the substrate module 110 further has a second substrate lateral side 110s2. The second light-emitting component 420 has a second element lateral side 420s2. A second wire receiving portion C2 is formed among the second conductive layer 114′, the second substrate lateral side 110s2 and the second element lateral side 420s2 to receive a wire. In detail, due to the design of the second wire receiving portion C2, the second conductive layer 114′ is exposed by the second wire receiving portion C2, such that the tool head for wire bonding can enter the second wire receiving portion C2 to conveniently form a wire on the exposed second conductive layer 114′.

In other embodiments, the insulating pad 127 of FIG. 8 can be replaced with the insulating filling layer 330 of FIG. 3A.

The light-emitting device 500 can be disposed on the circuit board 11. The circuit board 11 includes a first pad 11a, a second pad 11b and a third pad 11c. The first conductive layer 113 of the light-emitting device 500 is electrically connected to the second pad 11b through the first wire 12, and the second conductive layer 114 of the light-emitting device 500 is electrically connected to the third pad 11c through the second wire 13. Under such design, although the substrate 111 is an insulating substrate, the light-emitting device 500 remains electrically connected to the circuit board 11 through the first wire 12 and the second wire 13. Besides, the third conductive layer 115 and the first pad 11a can be conductively or ion-conductively connected. The light-emitting device 500 can further be connected to the first pad 11a through the third conductive layer 115, such that the heat generated by the light-emitting device 500 can be conducted to the circuit board 11 through the second electrode 126′, the second conductive layer 114′ disposed in the first opening 112a, the substrate 111, the third conductive layer 115 and the first pad 11a to dissipate the heat. In another embodiment, the heat generated by the light-emitting device 500 can be conducted to the circuit board 11 through the first electrode 125, the first conductive layer 113 disposed in the first opening 112a (not illustrated), the substrate 111, the third conductive layer 115 and the first pad 11a to dissipate the heat. It is not repeated here.

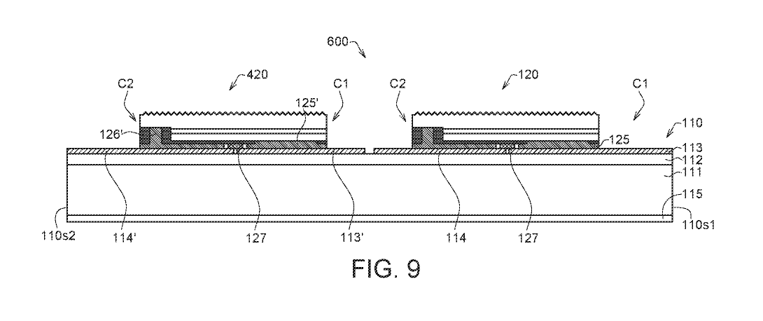

FIG. 9 shows a cross-sectional view of a light-emitting device 600 according to another embodiment of the invention. The light-emitting device 600 includes a substrate module 110, a first light-emitting component 120 and a second light-emitting component 420.

The substrate module 110 includes a substrate 111, an insulation layer 112, a first conductive layer 113, another first conductive layer 113′, a second conductive layer 114 and another second conductive layer 114′.

The first electrode 125 of the first light-emitting component 120 is connected to the first conductive layer 113. The second electrode 126 of the first light-emitting component 120 is connected to the second conductive layer 114. The first electrode 125′ of the second light-emitting component 420 is connected to the first conductive layer 113′. The second electrode 126′ of the second light-emitting component 420 is connected to the second conductive layer 114′. In the present embodiment, the second conductive layer 114 and the first conductive layer 113′ are separated from each other. However, the second conductive layer 114 and the first conductive layer 113′ still can be electrically connected through a wire (not illustrated) to connect the second electrode 126 of the first light-emitting component 120 and the first electrode 125 of the second light-emitting component 420.

Due to the design of the first wire receiving portion C1 and the second wire receiving portion C2, a wire can be connected to the first conductive layer 113 exposed by the first wire receiving portion C1, and another wire can be connected to the second conductive layer 114′ exposed by the second wire receiving portion C2, such that the light-emitting device 600 can be electrically connected to an external device through two wires.

In other embodiments, the insulating pad 127 of FIG. 9 can be replaced with the insulating filling layer 330 of FIG. 3A.

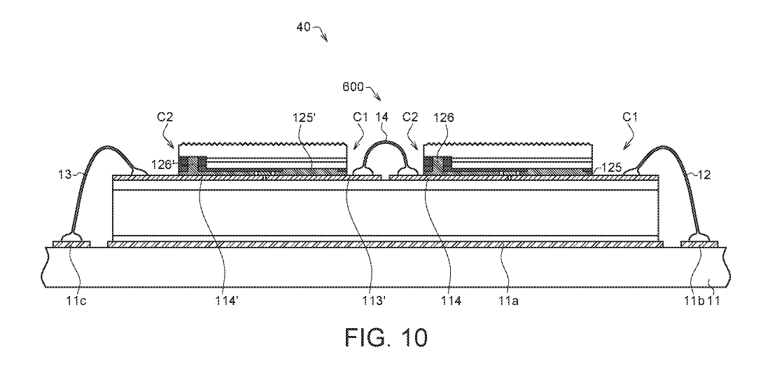

FIG. 10 shows a cross-sectional view of a light-emitting module 40 according to another embodiment of the invention. The light-emitting module 40 includes a light-emitting device 600, a circuit board 11, a first wire 12, a second wire 13 and a third wire 14.

The third wire 14 can connect the second conductive layer 114 and the first conductive layer 113′ which are separated from each other to electrically connect the second conductive layer 114 and the first conductive layer 113′. Thus, the first light-emitting component 120 and the second light-emitting component 420 can be electrically connected through the third wire 14.

The light-emitting device 600 can be disposed on the circuit board 11. The circuit board 11 includes a first pad 11a, a second pad 11b and a third pad 11c. The first conductive layer 113 of the light-emitting device 600 is electrically connected to the second pad 11b through the first wire 12. The second conductive layer 114′ of the light-emitting device 600 is electrically connected to the third pad 11c through the second wire 13. Under such design, although the substrate 111 is an insulating substrate, the light-emitting device 600 still can be electrically connected to the circuit board 11 through the first wire 12 and the second wire 13. Besides, the light-emitting device 600 can further be connected to the first pad 11a through the third conductive layer 115, such that the heat generated by the light-emitting device 600 can be conducted to the circuit board 11 through the light-emitting device 600, the third conductive layer 115 and the first pad 11a to dissipate the heat.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light-emitting component, comprising:
a semiconductor structure comprising a first semiconductor layer, a second semiconductor layer and a light emitting layer disposed between the first semiconductor layer and the second semiconductor layer;
a first insulation layer disposed over the semiconductor structure, the first insulation layer having a first opening exposing a portion of the first semiconductor layer and a second opening exposing the second semiconductor layer, wherein the first insulation layer comprises a single insulation layer or an insulation structure formed of multiple stacked insulation layers with different refractivities;
a first electrode layer and a second electrode layer disposed on the first insulation layer, wherein the first electrode layer is electrically connected to the first semiconductor via the first opening and the second electrode layer is electrically connected to the second semiconductor via the second opening; and
a pad layer disposed on the first insulation layer and located between the first electrode layer and the second electrode layer, wherein the pad layer is physically and electrically isolated from the first electrode layer and the second electrode layer.

2. The light-emitting component according to claim 1, wherein the first insulation layer comprises a Bragg reflector.

3. The light-emitting component according to claim 1, wherein the pad layer comprises an insulating pad.

4. The light-emitting component according to claim 1, wherein at least one of the first electrode layer and the second electrode layer comprises a multi-layer conductive structure.

5. The light-emitting component according to claim 4, wherein the multi-layer conductive structure is formed of at least one of gold, aluminum, silver, copper, rhodium (Rh), ruthenium (Ru), palladium (Pd), iridium (Ir), platinum (Pt), chromium, tin, nickel, titanium, tungsten (W), chromium alloy, titanium-tungsten alloy, nickel alloy, copper-silicon alloy, aluminum-copper-silicon alloy, aluminum silicon alloy, gold-tin alloy and combinations thereof.

6. The light-emitting component according to claim 1, wherein the light emitting layer comprises a multi-layer structure doped with silicon.

7. A light-emitting device, comprising:
a light-emitting component, comprising:
a semiconductor structure comprising a first semiconductor layer,
a second semiconductor layer and a light emitting layer disposed between the first semiconductor layer and the second semiconductor layer;
a first insulation layer disposed over the semiconductor structure, the first insulation layer having a first opening exposing a portion of the first semiconductor layer and a second opening exposing the second semiconductor layer, wherein the first insulation layer comprises a single insulation layer or an insulation structure formed of multiple stacked insulation layers with different refractivities;
a first electrode layer and a second electrode layer disposed on the first insulation layer, wherein the first electrode layer is electrically connected to the first semiconductor via the first opening and the second electrode layer is electrically connected to the second semiconductor via the second opening; and
a pad layer disposed on the first insulation layer and located between the first electrode layer and the second electrode layer, wherein the pad layer is physically and electrically isolated from the first electrode layer and the second electrode layer; and
a substrate module on which the light-emitting component is disposed, wherein the substrate module comprising a conductive substrate, a second insulation layer, a first conductive layer and a second conductive layer both disposed on the second insulation layer, and the second insulation layer is disposed on the conductive substrate and exposes a portion of the conductive substrate, and the first conductive layer is electrically connected to the conductive substrate, wherein the first electrode layer and the second electrode layer are electrically connected to the first conductive layer and the second conductive layer, respectively.

8. The light-emitting device according to claim 7, wherein the first conductive layer is electrically connected to the conductive substrate through an opening in the second insulation layer.

9. The light-emitting device according to claim 7, wherein an upper surface of the first type semiconductor layer, opposite to the light emitting layer and the substrate module, is exposed and the upper surface comprises a patterned structure.

10. The light-emitting device according to claim 7, wherein a first gap is formed between the first electrode and the second electrode of the first light-emitting component, and a second gap is formed between the first conductive layer and the second conductive layer, and the light-emitting device further comprises an insulating filling layer filled into the first gap and the second gap.

11. The light-emitting device according to claim 7, wherein the pad layer abuts on at least one of the first conductive layer and the second conductive layer.

12. A light-emitting component, comprising:
a first semiconductor layer, a second semiconductor layer and a light emitting layer disposed between the first semiconductor layer and the second semiconductor layer;
a reflective layer disposed on the second semiconductor layer;
a first electrode layer and a second electrode layer disposed on the reflective layer, wherein the first electrode layer is electrically connected to the first semiconductor and the second electrode layer is electrically connected to the second semiconductor; and
a pad layer disposed on the reflective layer and located between the first electrode layer and the second electrode layer, wherein the pad layer is physically and electrically isolated from the first electrode layer and the second electrode layer.

13. The light-emitting component according to claim 12, wherein the reflective layer comprises a Bragg reflector.

14. The light-emitting component according to claim 12, wherein the pad layer comprises an insulating pad.

15. The light-emitting component according to claim 12, wherein at least one of the first electrode layer and the second electrode layer comprises a multi-layer conductive structure.

16. The light-emitting component according to claim 15, wherein the multi-layer conductive structure is formed of at least one of gold, aluminum, silver, copper, rhodium (Rh), ruthenium (Ru), palladium (Pd), iridium (Ir), platinum (Pt), chromium, tin, nickel, titanium, tungsten (W), chromium alloy, titanium-tungsten alloy, nickel alloy, copper-silicon alloy, aluminum-copper-silicon alloy, aluminum silicon alloy, gold-tin alloy and combinations thereof.

17. The light-emitting component according to claim 12, wherein the light emitting layer comprises a multi-layer structure doped with silicon.
